(19) United States
(12) Patent Application Publication
(10) Pub. No.: US 2007/0267671 A1
(43) Pub. Date: Nov. 22, 2007

(54) TRENCH CAPACITOR HAVING LATERAL EXTENSIONS IN ONLY ONE DIRECTION AND RELATED METHODS

(75) Inventors: Kangguo Cheng, Beacon, NY (US); Lisa F. Edge, State College, PA (US); Johnathan E. Faltermeier, Fishkill, NY (US); Paul C. Parries, Wappingers Falls, NY (US); William C. Wille, Red Hook, NY (US)

Correspondence Address: HOFFMAN, WARNICK & D'ALESSANDRO LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/383,861

(22) Filed: May 17, 2006

(51) Int. Cl. H01L 29/94

(52) U.S. Cl. 257/301

(57) ABSTRACT

A trench capacitor and related methods are disclosed including a trench having lateral extensions extending in only one direction from the trench filled with a capacitor material. In one embodiment, the trench capacitor includes a trench within a substrate, and at least one lateral extension extending from the trench in only one direction, wherein the trench and each lateral extension are filled with a capacitor material. The lateral extensions increase surface area for the trench capacitor, but do not take up as much space as conventional structures.

### BACKGROUND OF THE INVENTION

1. Technical Field

The invention relates generally to semiconductor device fabrication, and more particularly, to a trench capacitor having lateral extensions in only one direction from the trench filled with a capacitor material, and related methods.

2. Background Art

Deep trenches are used in the semiconductor fabrication industry for, among other things, forming deep trench (DT) capacitors. As DT capacitors size has become smaller and the density of all structures on a semiconductor device has increased, the amount of space available for capacitor enhancements has diminished. One approach to improve capacitor performance is referred to as “bottling” and involves creating lateral openings, i.e., bottles, from both sides of a trench. The bottles are filled with a capacitor material, and thus increase the capacitive load of the capacitor. Unfortunately, due to the higher density devices very little space is left between trenches, thus preventing the use of bottling. In another approach, hemispherical silicon grain (HSG) is used to improve a capacitor by roughening the internal trench surface, but this approach decreases trench resistance.

In view of the foregoing, there is a need in the art for a solution to the problems of the related art.

### SUMMARY OF THE INVENTION

A trench capacitor and related methods are disclosed including a trench having lateral extensions extending in only one direction from the trench filled with a capacitor material. In one embodiment, the trench capacitor includes a trench within a substrate, and at least one lateral extension extending from the trench in only one direction, wherein the trench and each lateral extension are filled with a capacitor material. The lateral extensions increase surface area for the trench capacitor, but do not take up as much space as conventional structures.

A first aspect of the invention provides a trench capacitor comprising: a trench within a substrate, the trench including at least one lateral extension extending from the trench, all of the at least one lateral extensions extending in only one direction from the trench, wherein the trench and each lateral extension are filled with a capacitor material.

A second aspect of the invention provides a method of forming a trench capacitor, the method comprising: forming a trench for the trench capacitor in a substrate; forming a lateral opening in only one direction from the trench; and filling the trench and the lateral opening with a capacitor material.

A third aspect of the invention provides a method of forming a trench capacitor, the method comprising: forming at least one dopant region in a substrate; forming a mask including a pattern for a trench that intersects only one end of the at least one dopant region; etching to form the trench and remove the at least one dopant region to form at least one lateral opening extending in only one direction from the trench; and filling the trench and the at least one lateral opening with a capacitor material.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows one embodiment of a trench capacitor according to the invention.

FIGS. 2-6 show one embodiment of a method of forming a trench capacitor according to the invention.

FIGS. 7A-10 show another embodiment of a method of forming a trench capacitor according to the invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

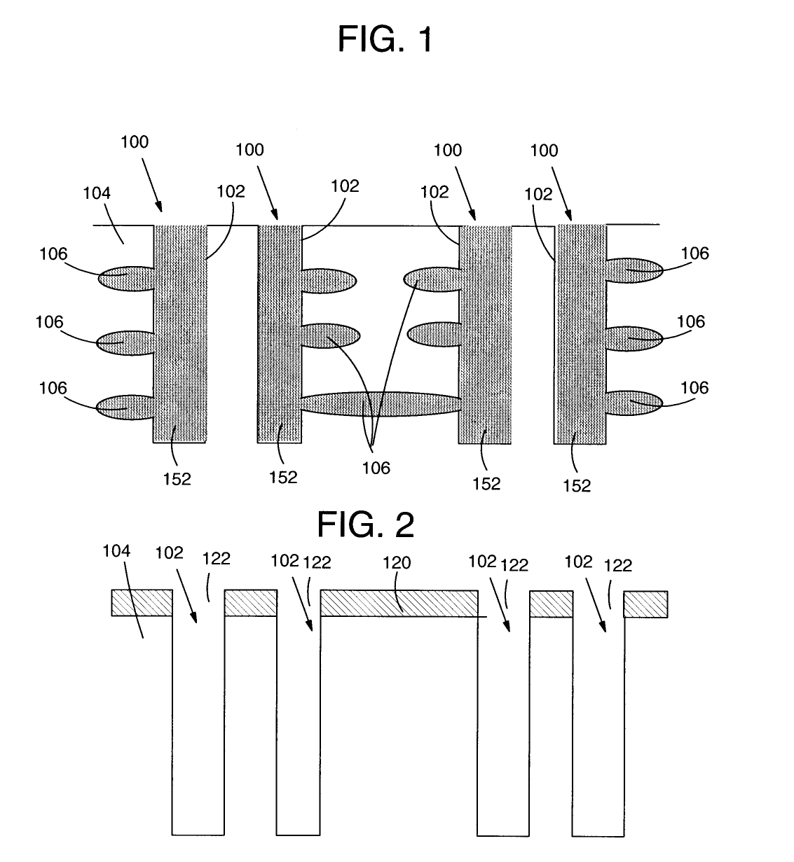

Turning to the drawings, FIG. 1 shows one embodiment of a trench capacitor 100 (four shown) according to the invention. Trench capacitor 100 includes a trench 102 within a substrate 104 and at least one lateral extension 106 extending from trench 102. All of lateral extension(s) 106, however, extend in only one direction from trench 102. Substrate 104 may include silicon, silicon germanium, semiconductor-on-insulator or any other now known or later developed substrate material. Trench 102 and each lateral extension 106 are filled with a capacitor material 152 such as polysilicon or a metal. As illustrated, one set of lateral extensions of two trenches in the middle of FIG. 1 are interconnected (bottom one), however, etching typically stops before two lateral extensions interconnect. Hence, this interconnection is not necessary. In addition, although a plurality of lateral extensions 106 are illustrated for each trench 102, any number, including one, may be used. All lateral extension(s) 106 extend from a respective trench 102 in only one direction. That is, lateral extensions 106 extend asymmetrically from a respective trench 102. As a result, trench capacitor 100 provides increased trench area and corresponding capacitive load, but uses less space than conventional structures.

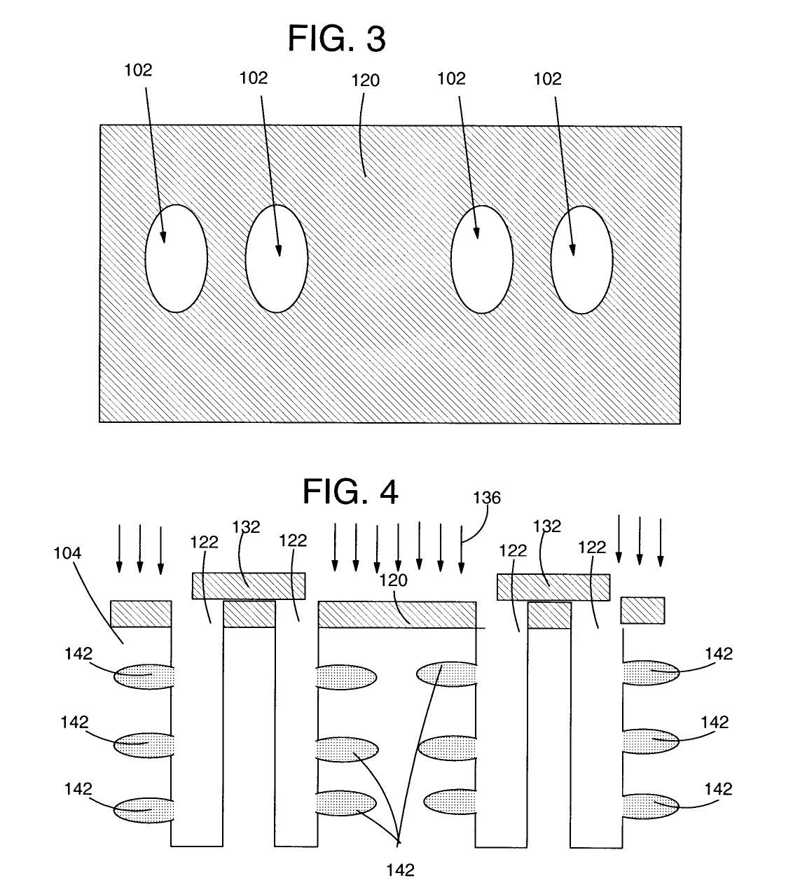

Turning to FIGS. 2-6, one embodiment of a method of forming a trench capacitor 100 according to the invention will now be described. In a first step, shown in FIG. 2, a trench 102 for trench capacitor 100 (FIG. 1) is formed in substrate 104 in any now known or later developed manner. For example, a mask 120 may be formed, patterned and etched to create openings 122, which are used for etching trench 102. FIG. 3 shows a top view of the structure of FIG. 2.

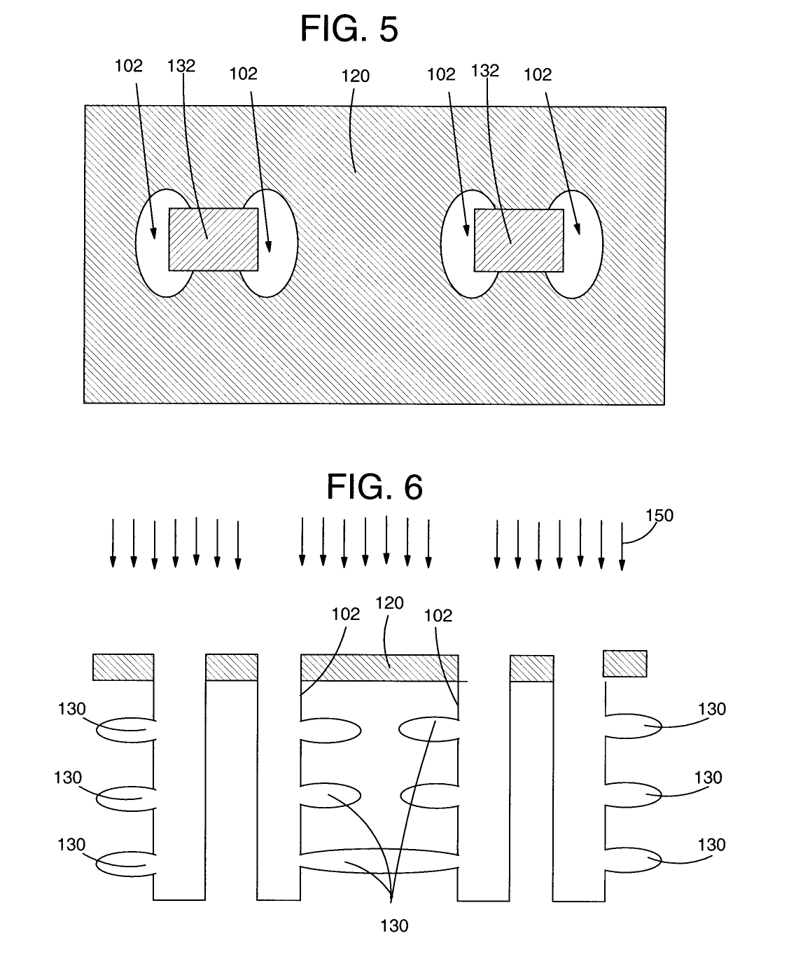

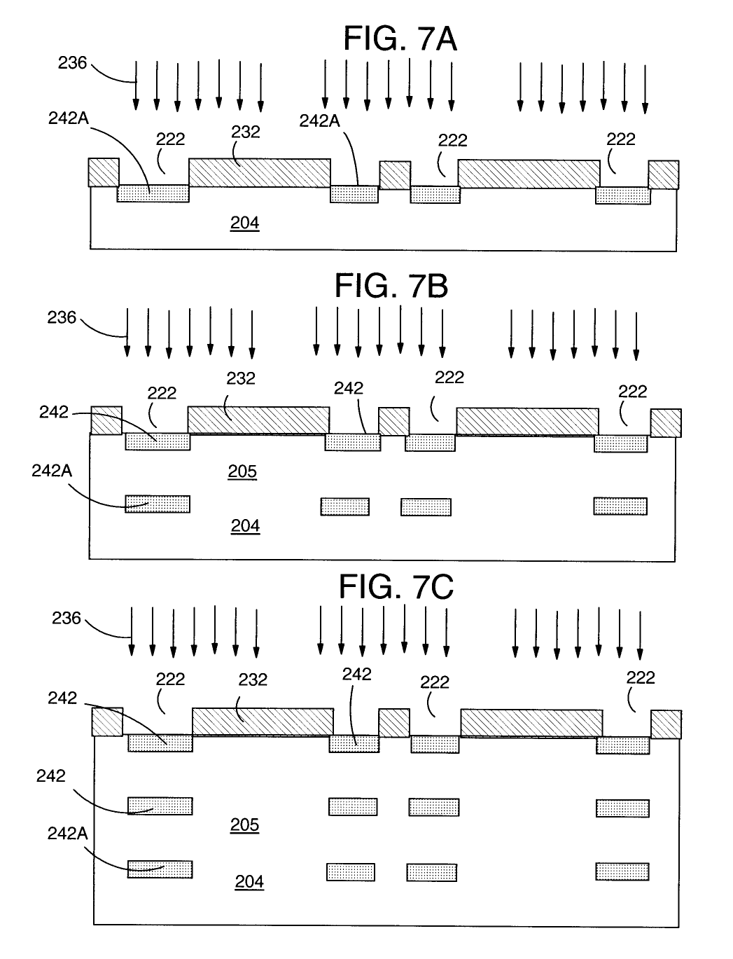

FIGS. 4-6 show the next step of forming a lateral opening 130 (FIG. 6) in only one direction from trench 102. A first part of this step may include, as shown in FIG. 4, forming a mask 132 covering only a portion of opening 122 to trench 102. Mask 132 may be referred to as an “asymmetric mask” because it is not aligned with opening 122. Next, as also shown in FIG. 4, an ion implantation 136 of a dopant to form a dopant region 142 that defines an opening location within substrate 104 is performed. In one embodiment, the dopant is an N-type dopant, which may include, for example, phosphorus (P), arsenic (As), antimony (Sb) or other n-type dopants. Alternatively, the dopant may be a P-type dopant, which may include, for example, boron (B), indium (In) or other p-type dopants. Where numerous lateral extensions 106 (FIG. 1) are desired, the ion implanting step may include ion implanting the dopant to form a plurality of dopant regions 142 at different depths within substrate 104. That is, ion implantation 136 using different energy levels may be employed to form dopant regions 142 within substrate 104 at different depths. Each dopant region 142 that defines an opening location intersects a trench 102. FIG. 5 shows a top view of the structure of FIG. 4.

FIG. 6 shows a next step of etching 150 to remove dopant region 142 (FIG. 4) and form a lateral opening 130 extending from trench 102. As illustrated, one set of lateral extensions of two trenches (bottom set) in the middle of FIG. 6 are shown interconnected, however, etching typically stops before two lateral extensions interconnect. Hence, this interconnection is not necessary. Mask 132 (FIG. 5) may be removed prior to this step or in a later process. Etching 150 may include a reactive ion etch (RIE), a wet etch or other etching processes that allow opening of lateral openings 130. For example, the etching 150 may include chlorine (Cl₂) and helium (He). In one embodiment, etching 150 has a bias power of zero such that the reactive ions are not accelerated toward substrate 104 (FIG. 4). As a result, there is no significant physical component to etching 150, resulting in an isotropic chemical etch wherein doped silicon is etched very selectively compared to un-doped silicon. One illustrative etching 150 chemistry is as follows: pressure: approximately 50 milli-Torr (mT), power responsible for creating reactive ions: approximately 700 Watts (W); bias power: 0 W; approximately 100 standard cubic centimeters per minute (sccm) chlorine (Cl₂) and approximately 50 sccm helium (He). Other etching chemistries may also be used. Note that lateral openings 130 do not extend into or out of the page in an extent that would cause collapse.

Returning to FIG. 1, a final step may include filling trench 102 and lateral opening(s) 130 (FIG. 6) with a capacitor material 152 to arrive at trench capacitor 100. Capacitor material 152 may include a ‘second plate’ material, e.g., a dielectric layer such as silicon nitride, and then a conductor material such as polysilicon or any other now known or later developed material used for trench capacitors. These layers have not been shown for clarity and because they include well known materials. The filling step may include using any suitable implantation and/or deposition technique such as chemical vapor deposition (CVD), low-pressure CVD (LPCVD), plasma-enhanced CVD (PECVD), semi-atmosphere CVD (SACVD), high density plasma CVD (HDPCVD), atomic-layer deposition (ALD), plating, etc.

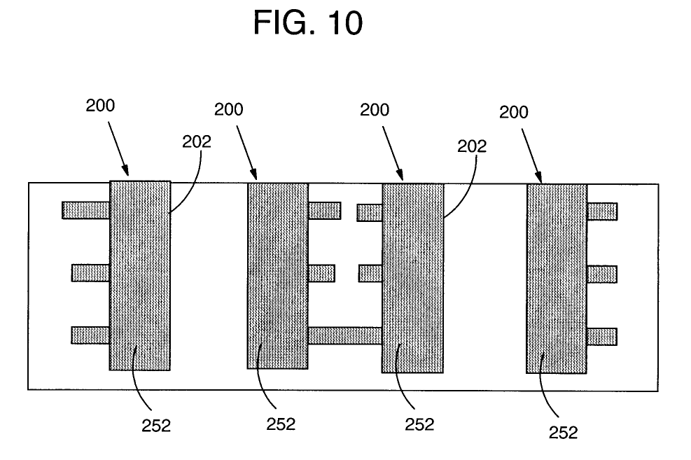

Turning to FIGS. 7A-10, another embodiment of a method of forming a trench capacitor 200 (FIG. 10) will now be described. FIGS. 7A-7C show a first step including forming at least one dopant region 242 in a substrate 204. As described above, in one embodiment, the dopant may be N-type dopant such as phosphorus (P), arsenic (As), antimony (Sb) or other n-type dopants. Alternatively, the dopant may be a P-type dopant, which may include, for example, boron (B), indium (In) or other p-type dopants. Substrate 204 may include silicon, silicon germanium, semiconductor-on-insulator or any other now known or later developed substrate material. As illustrated, this step may include forming a plurality of dopant regions 242 at different depths within substrate 204. In order to achieve this structure, this step may include forming a mask 232 over substrate 204, the mask having an opening 222 therein. Next, as shown in FIG. 7A, the dopant is ion implanted 236 into substrate 204 through opening 222 to form a first dopant region 242A. Next, mask 232 is removed (one shown is a new one) in any known manner, and, as shown in FIG. 7B, another layer 205 of substrate 204 is epitaxially grown to embed first dopant region 242A. The above-described steps may then be repeated. That is, mask 232 forming, ion implanting, mask removing and epitaxially growing steps may be repeated to form at least one other dopant region 242 in substrate 204 at a different depth than first dopant region 242A. Any number of dopant regions 242 at any number of levels may be formed in this manner. FIG. 7C shows another layer of dopant regions 242. Each mask 232 is shown having openings 222 to form dopant regions 242 in an aligned fashion, however, this is not necessary.

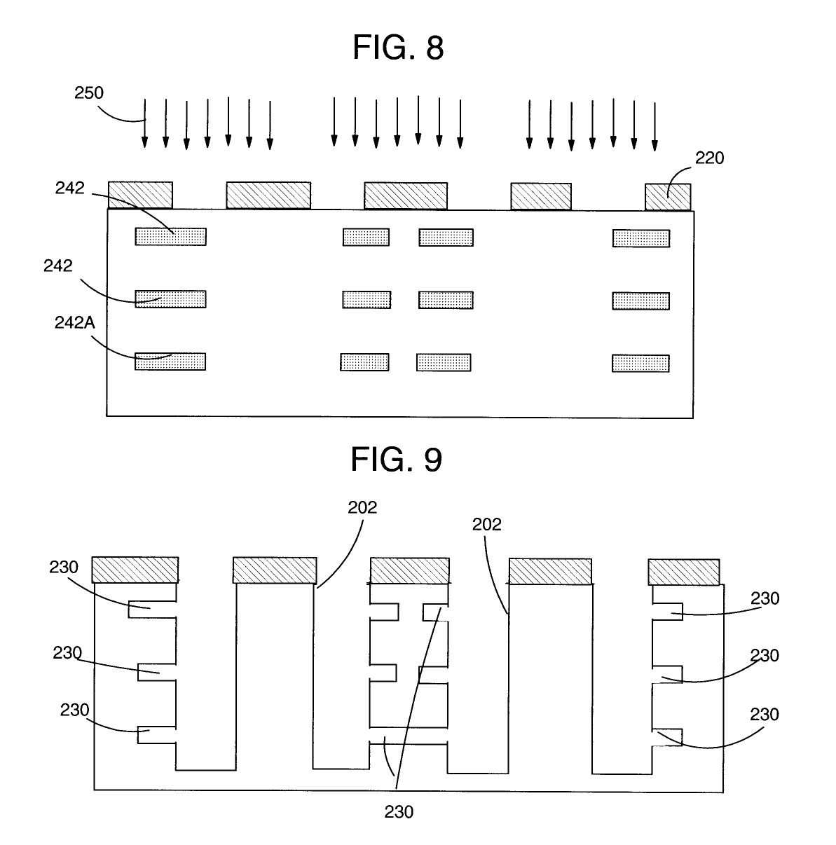

Next, as shown in FIG. 8, a mask 220 may be formed including a pattern for a trench 202 (FIG. 9) that intersects only one end of the at least one dopant region 242. Etching 250 is performed next to form trench 202 and remove dopant region(s) 242 to form at least one lateral opening 230 (FIG. 9), with all lateral opening(s) 230 (FIG. 9) extending in only one direction from trench 202. That is, etching 250 forms trench 202 and removes each dopant region(s) 242 to form a plurality of lateral openings 230 (FIG. 9), all extending in only one direction from trench 202. As illustrated, one set of lateral extensions of two trenches in the middle of FIG. 9 are interconnected (bottom set), however, etching typically stops before two lateral extensions interconnect. Hence, this interconnection is not necessary. Etching 250 may include a reactive ion etch (RIE), a wet etch or other etching processes that allow opening of lateral openings 130. Note that lateral openings 230 do not extend into or out of the page in an extent that would cause collapse. Mask 220 may then be removed.

As shown in FIG. 10, trench capacitor 200 may be completed by filling trench 202 and the at least one lateral opening 230 (FIG. 9) with a capacitor material 252. (Note, the bottom set of lateral extensions are shown interconnected, but this is not necessary). Capacitor material 252 may include a ‘second plate’ material, e.g., a dielectric layer such as silicon nitride, and then a conductor material such as polysilicon or any other now known or later developed material used for trench capacitors. These layers have not been shown for clarity and because they include well known materials. The filling step may include using any suitable implantation and/or deposition technique such as chemical vapor deposition (CVD), low-pressure CVD (LPCVD), plasma-enhanced CVD (PECVD), semi-atmosphere CVD (SACVD), high density plasma CVD (HDPCVD), atomic layer deposition (ALD), plating, etc. Trench capacitor 200 includes substantially the same structure as trench capacitor 100 (FIG. 1).

Masks 120, 132, 220, 232 may be formed in any now known or later developed manner and may include any suitable material for the etching chemistry involved.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A trench capacitor comprising:
a trench within a substrate, the trench including at least one lateral extension extending from the trench, all of the at least one lateral extensions extending in only one direction from the trench,
wherein the trench and each lateral extension are filled with a capacitor material.

2. The trench capacitor of claim 1, wherein the at least one lateral extension includes a plurality of lateral extensions.

3. The trench capacitor of claim 1, wherein the capacitor material includes a dielectric layer and a polysilicon.

4. A method of forming a trench capacitor, the method comprising:
forming a trench for the trench capacitor in a substrate;
forming a lateral opening in only one direction from the trench; and
filling the trench and the lateral opening with a capacitor material.

5. The method of claim 4, wherein the lateral opening forming includes:
forming a mask covering only a portion of an opening to the trench;
ion implanting a dopant to form a dopant region within the substrate; and
etching to remove the dopant region and form the lateral opening.

6. The method of claim 5, wherein the lateral opening includes a plurality of lateral openings, the ion implanting includes ion implanting the dopant to a plurality of dopant regions at different depths within the substrate, and the etching includes forming the plurality of lateral openings.

7. The method of claim 5, wherein the dopant includes a dopant selected from the group consisting of: phosphorus (P), boron (B), arsenic (As), antimony (Sb), and indium (In).

8. The method of claim 5, wherein the etching uses zero bias power.

9. The method of claim 5, wherein the etching includes one of a reactive ion etch and a wet etch.

10. The method of claim 4, wherein the capacitor material includes a dielectric layer and a polysilicon.

11. A method of forming a trench capacitor, the method comprising:
forming at least one dopant region in a substrate;
forming a mask including a pattern for a trench that intersects only one end of the at least one dopant region;
etching to form the trench and remove the at least one dopant region to form at least one lateral opening extending in only one direction from the trench; and
filling the trench and the at least one lateral opening with a capacitor material.

12. The method of claim 11, wherein the dopant includes an N-type dopant.

13. The method of claim 12, wherein the N-type dopant is selected from the group consisting of: phosphorus (P), arsenic (As) and antimony (Sb).

14. The method of claim 11, wherein the dopant region forming includes forming a plurality of dopant regions at different depths within the substrate,
wherein the etching forms the trench and removes each of the at least one dopant regions to form a plurality of lateral openings extending from the trench, all of the lateral openings extending in only one direction from the trench, and the filling step fills the trench and each lateral opening.

15. The method of claim 14, wherein the dopant region forming includes:
forming a mask over the substrate, the mask having an opening therein;
ion implanting the dopant into the substrate through the opening to form a first dopant region;
removing the mask;
epitaxially growing another layer of the substrate to embed the first dopant region; and
repeating the mask forming, the ion implanting, the mask removing and the epitaxially growing to form at least one other dopant region in the substrate at a different depth than the first dopant region.

16. The method of claim 14, wherein the dopant includes a dopant selected from the group consisting of: phosphorus (P), boron (B), arsenic (As), antimony (Sb), and indium (In).

17. The method of claim 11, wherein the etching uses zero bias power.

18. The method of claim 11, wherein the etching forms a plurality of lateral openings.

19. The method of claim 11, wherein the etching includes one of a reactive ion etch and a wet etch.

20. The method of claim 11, wherein the capacitor material includes a dielectric layer and a polysilicon.
